(19) United States
(12) Patent Application Publication
(10) Pub. No.: US 2025/0365852 A1
(43) Pub. Date: Nov. 27, 2025

(54) BACKPLATE AND METHOD FOR PROTECTING AND COOLING A PRINTED CIRCUIT BOARD

(71) Applicant: Advanced Micro Devices, Inc., Santa Clara, CA (US)

(72) Inventors: Tingyu LIU, Shanghai (CN); Jianming JIN, Shanghai (CN); Xiaoxu LI, Shanghai (CN)

(21) Appl. No.: 18/670,701

(22) Filed: May 21, 2024

(51) Int. Cl. H05K 1/02; H05K 7/20

(52) U.S. Cl. CPC H05K 1/0209; H05K 7/20481; H05K 2201/066

(57) ABSTRACT

Disclosed herein are a backplate for a PCB and a method for protecting and cooling a PCB and its backside components. The backplate, which can be attached to a backside of a PCB, includes a second sheet sandwiched between a first sheet and a third sheet. The backplate may include a thermal pad penetrating the first sheet and contacting the second sheet. The second sheet has a higher thermal conductivity than the conductivities of the first and third sheets.

### TECHNICAL FIELD

Embodiments of the present invention generally relate to a backplate for a printed circuit board, and in particular, to a thin backplate comprising a plurality of layers.

BACKGROUND

Peripheral Component Interconnect Express (PCIe) specifies a high-speed bus standard that is getting widely adopted. PCIe requires very tight mechanical dimensions for printed circuit boards (PCBs) to ensure compatibility between different devices and systems. For example, PCIe has a height constraint to the backside of a PCB to as small as 2.67 mm. To comply with the PCIe standard, traditional backplates need to become much thinner without sacrificing the performances for heat dissipation, shielding, and other functions.

It is worth noting that current electronic devices for data centers and AI are computing and memory intensive. For example, more and more memory (MEM) capacities are added to graphic cards, causing the cards to generate more and more heat. As the graphic cards are still mounted on PCBs and then installed in electronic devices, PCBs need to have improved heat dissipation function while the physical dimension is shrinking.

The backplate for PCB provides several protective functions, such as dissipating heat generated by various components of the PCB, protecting the PCB from an external impact, and shielding PCB components from electromagnetic interference. FIG. 1 illustrates an example of a backplate 102 attached to a bottom surface 104 of a PCB 100. The backplate 102 is attached to the PCB 100 by fasteners 106. The backplate 102 has an inner region 108 that contacts with the PCB 100. (See U.S. Pat. No. 11,831,094) Traditional backplates often are made of copper or aluminum with many cutouts to accommodate components placed at the backside of a PCB.

Therefore, a need exists for an improved backplate for a printed circuit board.

### SUMMARY

Disclosed herein are an improved backplate for a PCB, a PCB having the improved backplate, and a method for protecting the PCB. In an example, the backplate includes a second sheet sandwiched between a first sheet and a third sheet. The first sheet, the second sheet, and the third sheet are all capable of dissipating heat. The first sheet is disposed between a backside of the PCB and the second sheet. The second sheet has a higher conductivity than those of the first sheet and the third sheet and is configured to spread heat faster than the other two sheets and eventually dissipate heat via the third sheet. The backplate further includes a thermal pad penetrating the first sheet and contacting the second sheet. The thermal pad can quickly transmit heat from an electronic component of the PCB to the second sheet, bypassing the first sheet.

According to various embodiments, the backplate may further includes an electrical insulating layer disposed between the first sheet and the second sheet, the thermal pad penetrating the electrical insulating layer. The backplate may further includes an adhesion layer disposed between the second sheet and the third sheet. The first sheet includes stainless steel, the second sheet includes graphite, and the third sheet includes stainless steel.

According to another embodiment, the backplate complies with the specification of PCIe. For example, a height of the backplate is no greater than about 2.67 mm.

According to yet other embodiments, the thermal pad does not penetrate the second sheet. The first sheet includes a plurality of out-of-plane ribs formed by grooves. The third sheet includes a first raised wall along a first edge of the third sheet and a second raised wall along a second edge of the third sheet, the first raised wall being substantially perpendicular to the second raised wall. The first raised wall and the second raised wall extend from the third sheet toward the first sheet. The backplate further includes a plurality of separators attached to the third sheet, the separators extending through the second sheet and the first sheet.

In an example, a printed circuit board includes a front side having a plurality of electrical components; a backside having a plurality of solder connections of the plurality of the electrical components; and a backplate disposed along the backside and configured according to various embodiments of the present disclosure.

In another example, the method of protecting a printed circuit board (PCB), includes shielding a backside of the PCB by a backplate that is configured according to various embodiments of the present disclosure, transferring first thermal energy from the PCB to the first sheet, then to the second sheet, then to the third sheet; transferring second thermal energy from the PCB to a thermal pad, then to the second sheet, then to the third sheet; and maintaining a clearance gap between the first sheet and the backside by using a plurality of separators.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a known configuration of a backplate attached to a PCB.

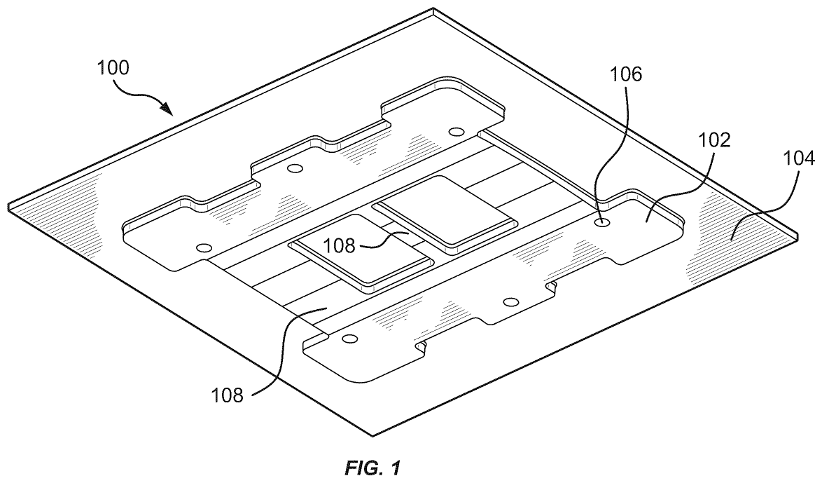

FIG. 2 illustrates a schematic electronic device having a plurality of PCBs and backplates, according to an embodiment of the present disclosure.

FIG. 3 illustrates a schematic perspective view of a backplate, according to an embodiment of the present disclosure.

FIG. 4 illustrates a schematic exploded view of a backplate, according to an embodiment of the present disclosure.

FIG. 5 illustrates a schematic cross-sectional view of a backplate along lines A-A in FIG. 3, according to an embodiment of the present disclosure.

FIG. 6 illustrates a method of protecting a PCB, according to an embodiment of the present disclosure.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are a backplate for a PCB and a method for dissipating heat via the backplate. The backplate includes a middle sheet made of a material having high thermal conductivity. The middle sheet is protected by an outer sheet and an inner sheet, both of which are made of materials having high mechanical strength. In an example, the middle sheet is made of graphite, while the inner sheet and the outer sheet are made of stainless steel. The backplate as set forth in the present disclosure provides a balanced design among several functions, such as dissipating the heat, protecting the PCB, and lowering the cost,

In an embodiment, the stack-up height from PCB backside to backplate outer surface is no greater than 2.67 mm to comply with the specification of PCIe. The backplate may also include a plurality of thermal pads coupled directly with the middle sheet. The thermal pads are disposed underneath and contact with electronic components that generate a great amount of heat, such as processors and memories. The backplate may also include structures configured to increase the stiffness of the backplate. The structures include ribs formed on an inner surface, raised walls formed along the edges, or other structures. The backplate also includes separators configured to maintain a clearance gap between the inner surface of the backplate and the PCB. The backplate as set forth in the present disclosure, although very thin, can provide adequate mechanical stiffness for handling and shielding purposes.

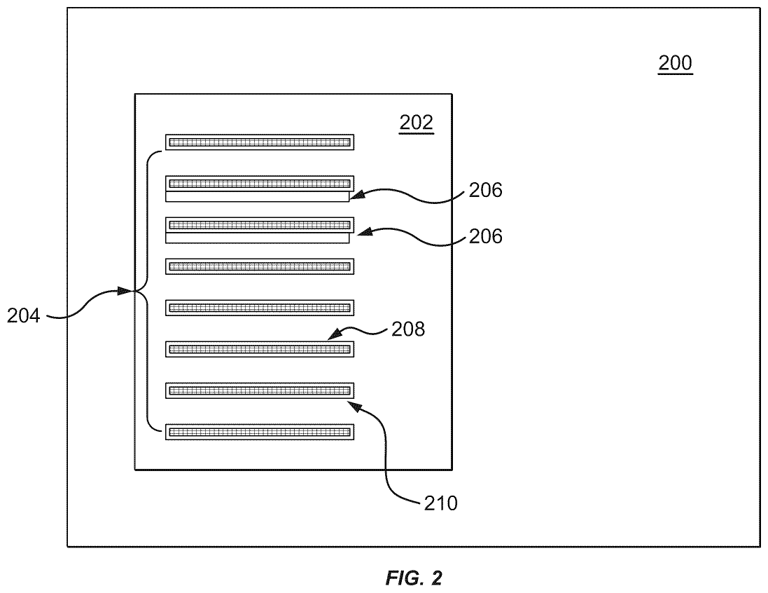

Now turning to FIG. 2, which illustrates a schematic configuration of an electronic system, according to an embodiment of the present disclosure. The electronic device 200 may be a computer, a datacenter, an AI inference engine, an AI platform, or any machine having a PCB. In an embodiment, the electronic device 200 includes a motherboard 202 which includes a plurality of PCBs 204. The electronic device 200 may also include other components, such as a display, a keyboard, and a central processing unit, which are not shown for brevity. In an embodiment, the electronic device 200, the motherboard 202, and the PCBs 204 comply with the PCIe standard.

One or more of the PCBs 204 include a backplate 206 attached to a backside of 210 of the PCB 204. The backplate 206 is configured according to various embodiments of the present disclosure. In the present disclosure, a backside 210 of a PCB may be understood as the solder side or the secondary side, which has many solder connections. The backside 210 of the PCB 204 may also include limited electronic components, such as memories and capacitors. The backside 210 is opposite to a front side 208 of the PCB 204. The front side 208 of the PCB 204 refers to a component side or a primary side, to which many electronic components are attached. The electronic components attached to the front side 208 may include processors, memories, FPGAs, integrated circuits, transmitters, receivers, MEMS, and other electronic components. These electronic components run on electricity and generate heat during operation.

In an embodiment, the PCBs 204 comply with the specification of PCIe. For example, the height of the backside 210 of the PCB 204 is no greater than 2.67 mm.

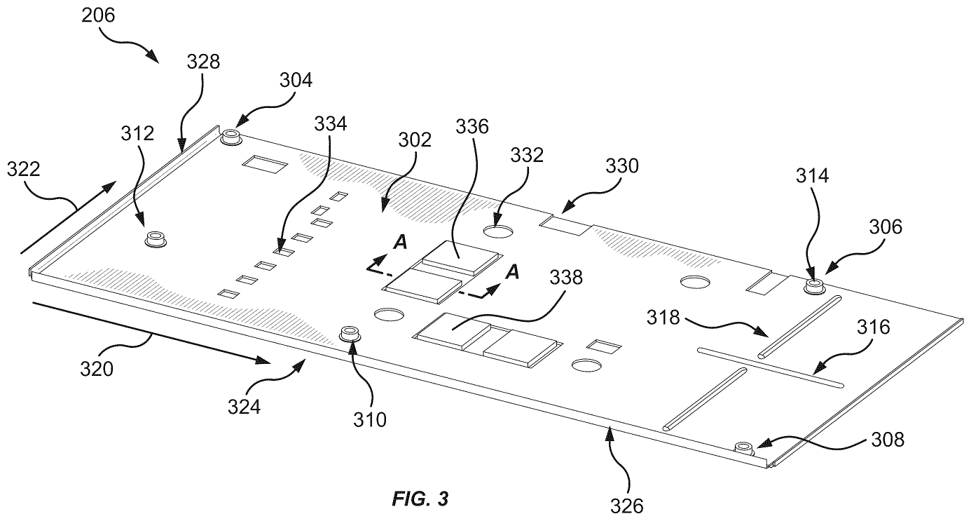

FIG. 3 illustrates a schematic perspective view of the backplate 206, according to an embodiment of the present disclosure. The backplate 206 is configured to be disposed at a backside of a PCB and substantially cover the entire surface of the backside. The backplate 206 may be in any shape that conforms to the shape of the PCB 204.

As shown in FIG. 3, the backplate 206 has a rectangular shape and includes a longitudinal direction 320 and a transverse direction 322. The backplate 206 also includes an inner surface 302 that faces the backside 210 of the PCB 204 (shown in FIG. 2) and an outer surface 324 that is opposite to the inner surface 302. The inner surface 302 may have a plurality of cutouts, depressions, protrusions, and other structures, while the outer surface 324 may be substantially flat and solid.

The backplate 206 also includes a plurality of separators 304, 306, 308, 310, 312 configured to separate the inner surface 302 from the backside 210 of the PCB 204. The plurality of separators 304, 306, 308, 310, 312 generate a clearance gap such that the inner surface 320 does not contact the backside 210 of the PCB 204. In an embodiment, at least one separator, such as the separator 306, includes a bore 314 configured to allow a fastener (not shown) to pass through. The fastener can be used to secure the backplate 206 to the PCB 204 and may include bolts, screws, clips, or other fasteners.

As the backplate 206 is very thin and long, the backplate 206 alone is not very rigid. In an embodiment, the backplate 206 includes a plurality of mechanisms for increasing a mechanical stiffness of the backplate 206. For example, the inner surface 302 may include a plurality of ribs 316, 318 formed by out-of-plane depressions, such as long grooves. In an embodiment the transverse rib 318 substantially extends between the two longitudinal edges 326. The longitudinal rib 316 is disposed in parallel with the longitudinal edges 326 and may intersect with the longitudinal rib 318. Upon intersection, the longitudinal rib 316 may be kept contiguous as the mechanical stiffness along the longitudinal direction is weaker than that of the transverse direction. The ribs 316 and 318 may be separately disposed at any suitable area of the inner surface 302. In an embodiment, the ribs 316 and 318 are formed by pressing the inner surface 302 toward the outer surface 324. In another embodiment, the ribs 316, 318 may be formed by attaching additional structures to the inner surface 302. The plurality of ribs 316, 318 are disposed to increase the rigidity of the backplate 206 in both the longitudinal direction and the transverse direction.

In an embodiment, edges of the backplate 206 may be shaped to increase the mechanical stiffness of the backplate 206. For example, a raised wall 326 may be formed along the longitudinal edge, and another raised wall 328 may be formed along the transverse edge. The raised walls 326 and 326 are perpendicular to each other. Additional raised walls (not shown) may be formed along other edges of the backplate 206. Raised walls 326 and 328 are configured to extend from the outer surface 324 toward the PCB 204 to avoid increase the height of the backplate 206.

In an embodiment, the inner surface 302 includes a plurality of cutouts 330, 332, 334 configured to accommodate electronic components that extend out of the surface of the backside 210 of the PCB 204. The plurality of cutouts 330, 332, 334 may be disposed at any location or in any shape that are determined by the location and shape of the electronic components of the PCB 204. In an embodiment, the bottom surface 324 is devoid of cutouts for electronic components, but may have holes for fasteners to pass through. The inner surface 302 may also include a plurality of thermal pads 336, 338 configured to contact with electrical components of the PCB 204 and dissipate heat thereof. In an embodiment, the thermal pads 336, 338, the ribs 316, 318, and the cutouts 330, 332, 334 do not penetrate the outer surface 324, leaving the outer surface to be substantially solid. A thermal pad 336, 338 as used in the present disclosure may be understood as a layer of material used to transfer heat from a component to the backplate 206. The thermal pads may be made from polymers filled with thermally conductive particles.

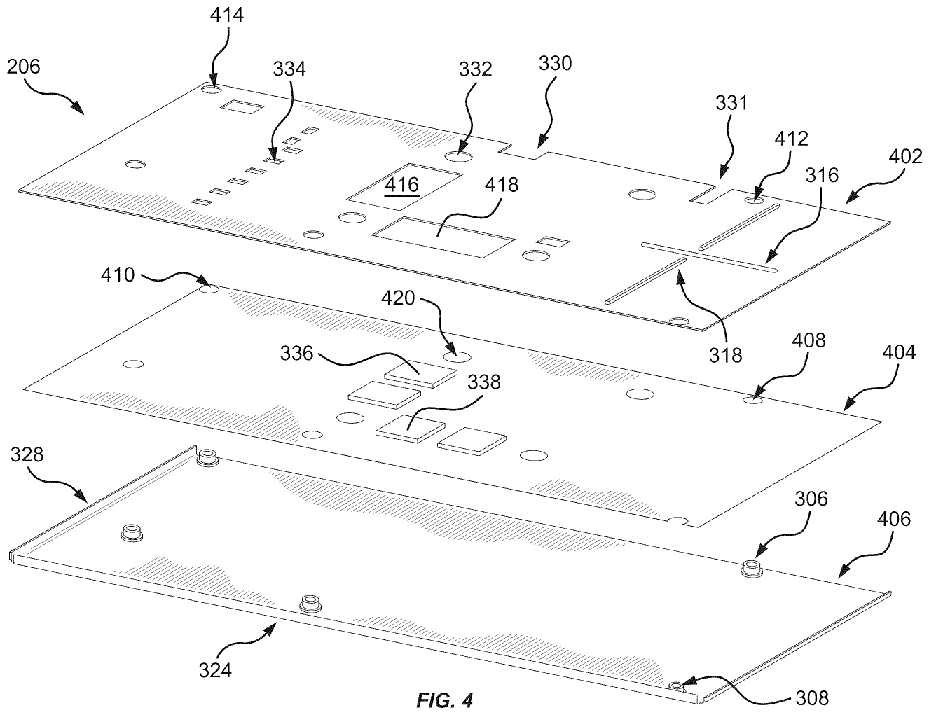

FIG. 4 illustrates a schematic exploded view of the backplate 206, according to an embodiment of the present disclosure. As shown in FIG. 4, the backplate 206 has a sandwich structure formed by a plurality of sheets, such as an inner sheet 402, a middle sheet 404, and an outer sheet 406. The plurality of sheets may include a high thermal conductivity sheet (such as the inner sheet 404) protected by at least two structural sheets (such as the inner sheet 402 and the outer sheet 406) disposed on the opposite sides of the high thermal conductivity sheet. Other layers of materials may be included in the backplate 206, such as an insulation layer disposed between the middle sheet 404 and the inner sheet 402, an adhesion layer disposed between the middle sheet 404 and the outer sheet 406, or any other suitable layer. In an embodiment, the thickness of the backplate 206 may be no greater than 1.0 mm, no greater than 0.8 mm, or no greater than 0.50 mm. The backplate 206, by using the plurality of sheets, can offer a good balance among cost, mechanical integrity, and heat dissipation.

In an embodiment, the inner sheet 402 covers the middle sheet 404 from a side of the backplate 206 that is adjacent to the backside of the PCB. The inner sheet 402 can be made of a first material with an acceptable thermal conductivity and a strong mechanical strength. The first material may include a stainless steel with a thermal conductivity of about 30 to 50 W/(m·K) and a Young's modulus of at least 160 GPa. In an example, the inner sheet 402 is formed by a steel plate cold commercial (SPCC). The inner sheet 402 may have a thickness of no greater than 0.3 mm or no greater than 0.2 mm.

The inner sheet 402 includes a plurality of cutouts configured to accommodate various components of the backplate 206 and/or the PCB. For example, the inner sheet 402 includes a plurality of first cutouts 332 and 334 for accommodating electrical components disposed on the backside of a PCB. The inner sheet 402 also includes a plurality of second cutouts 330 and 331 configured to accommodate alignment structures (not shown) disposed on the PCB. The cutouts 330 and 331 may be disposed along edges of the inner sheet 402. The inner sheet 402 may also include a plurality of third cutouts 416, 418 configured to allow thermal pads 336 and 338 to pass through. The inner sheet 402 may also include a plurality of fourth cutouts 412, 414 configured to allow the separators 306 to pass through. The inner sheet 402 also includes the plurality of ribs 316 and 318 configured to increase the mechanical stiffness of the backplate 206. The locations and shapes of the cutouts are not limited to those shown in FIG. 4 and can be adjusted according to different layouts of the PCBs.

In an embodiment, the middle sheet 404 is configured to dissipate heat much faster than the inner sheet 402. For example, the middle sheet 404 can quickly spread heat from a local hot spot to other areas. The middle sheet 404 can be made of a second material with a much higher thermal conductivity than the first material. The second material may have a thermal conductivity of at least 150 W/(m·K). Examples of the second material include graphite, copper, aluminum, graphene, or other material of a high thermal conductivity. In an embodiment, the thermal conductivity of the middle sheet 404 is at least three (3) times of that of the inner sheet. The middle sheet 404 may be much thinner than the inner sheet 402. For example, the middle sheet 404 may be a graphite sheet having a thickness of no greater than 0.1 mm or no greater than 0.05 mm. As a result, the thickness of the inner sheet 402 may be at least three (3) times or at least six (6) times of that of the middle sheet 404.

A plurality of heat dissipation structures 336, 338 are coupled to the middle sheet 404. The heat dissipation structures 336 and 338 can quickly transfer heat generated by certain electrical components (processors, memories, or FPGAs) of the PCB to the middle sheet 404. In an embodiment, the heat dissipation structures 336, 338 may be thermal pads, thermal paste, or other heat conductive structure. The thermal conductivity of the heat dissipation structures 336 and 338 may higher than that of the inner sheet 402. The heat dissipation structures may be made from polymers filled with thermally conductive particles.

In an embodiment, the middle sheet 404 includes a plurality of cutouts 408 and 410 configured to allow the separators 306 to pass through. The middle sheet 404 may also include cutouts 420 configured to accommodate taller electrical components disposed on the PCB. The cutouts 420 are aligned with the cutouts 332 of the inner sheet 402.

The outer sheet 406 is configured to provide an outer enclosure to the middle sheet 404. The outer sheet 406 may be made of the same material as the inner sheet 402 or may be made of a different material from the inner sheet 402. The outer sheet 406 may also have a similar thickness as the inner sheet 402. In an embodiment, the outer sheet 406 is substantially solid and flat without any cutouts. The separators 306 are attached to the outer sheet 406. In an embodiment, the raised walls 328 and 324 are formed in the outer sheet 406.

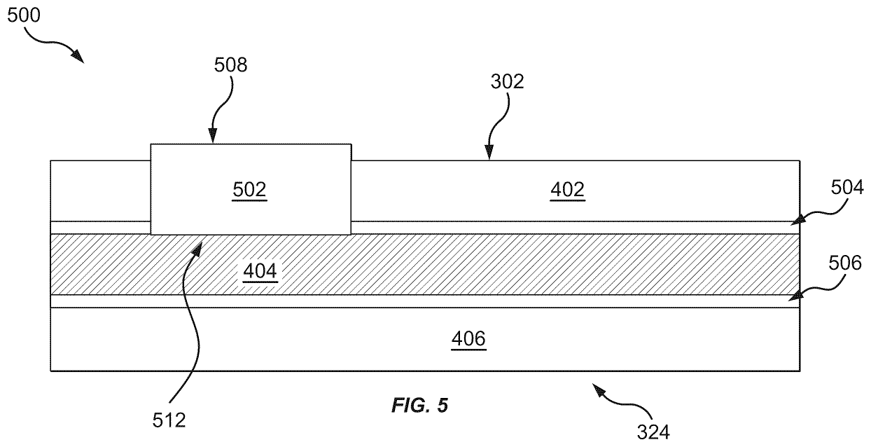

FIG. 5 illustrates a schematic cross-sectional view 500 of the backplate 206 along line A-A in FIG. 3, according to an embodiment. The cross-sectional view 500 shows an electrical insulating layer 504 disposed between the inner sheet 402 and the middle sheet 404. An adhesion layer 506 may be disposed between the middle sheet 404 and the outer sheet 406. The adhesion layer 506 is configured to bond the middle sheet 404 and the outer sheet 406. The adhesion layer 506 may be made of epoxy, silicon, resin, cyanoacrylate, or any other suitable adhesive. Additional coatings (not shown in FIG. 5), such as a layer of paint or polish, may be put on the inner surface and/or the bottom surface of the backplate.

The cross-sectional view 500 further shows a thermal pad 502 which couples directly to the middle sheet 404 after penetrating both the inner sheet 402 and the insulating layer 504. The thermal pad 502 has a bottom surface 512 that contacts with the middle sheet 404. The thermal pad 502 functions both as a thermal conductor and an electrical insulator. The thermal pad 502 may be formed by graphite or silicon embedded in ceramic. In an embodiment, the insulating layer 504 does not extend underneath the thermal pad 502 because the thermal pad 502 can be retained in position by a pressing force exerted by an electrical component and/or a compression force exerted by the inner layer 402. The thermal pad 502 is configured to be thicker than the inner sheet 402 such that the top surface 508 is higher than the inner surface 302 and contacts a surface of an electronic component of a PCB.

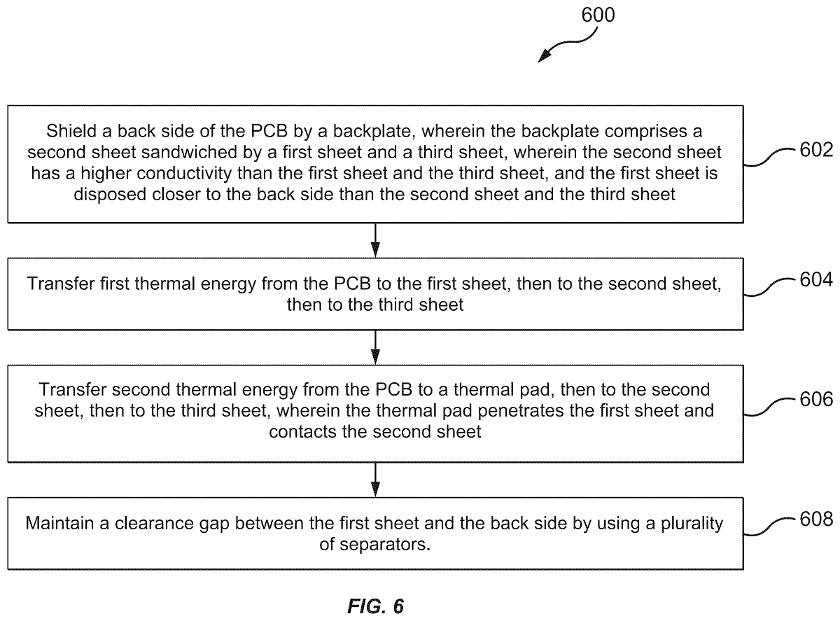

FIG. 6 illustrates a method 600 for protecting a PCB, according to an embodiment of the present disclosure. The method utilizes a backplate as set forth in the present disclosure to mechanically and thermally protect a PCB. At operation 602, a PCB of a computing system is shielded by a backplate configured according to various embodiment of the present disclosure. For example, a backside of the PCB is shielded by a backplate, which includes a second sheet (the middle sheet) sandwiched by a first sheet (the inner sheet) and a third sheet (the outer sheet). The second sheet has a higher conductivity than the first sheet and the third sheet, and the first sheet is disposed closer to the backside than the second sheet and the third sheet. At operation 604, when the computer system and the PCB are running, thermal energy is generated. A first portion of the thermal energy generated by the PCB is transferred from the PCB to the first sheet, then to the second sheet, then to the third sheet. At operation 606, a second portion of the thermal energy generated by the PCB is transferred from the PCB to a thermal pad, then to the second sheet, then to the third sheet. The thermal pad penetrates the first sheet and contacts the second sheet directly. The operations 604 and 606 occur substantially simultaneously. At operation 608, a clearance gap is maintained between the first sheet and the backside by using a plurality of separators such that unintended contacts between the inner sheet and the backside of the PCB is avoided.

While the foregoing is directed to embodiments of the present invention, other and further embodiments of the invention may be devised without departing from the basic scope thereof, and the scope thereof is determined by the claims that follow.

What is claimed is:

1. A backplate for a printed circuit board, comprising:
a first sheet;
a second sheet sandwiched between the first sheet and a third sheet, wherein the second sheet has a higher conductivity than that of the first sheet and the third sheet; and
a thermal pad penetrating the first sheet and contacting the second sheet.

2. The backplate of claim 1, further comprising an electrical insulation layer disposed between the first sheet and the second sheet.

3. The backplate of claim 2, wherein the thermal pad penetrates the electrical insulation layer.

4. The backplate of claim 3, further comprising an adhesion layer disposed between the second sheet and the third sheet.

5. The backplate of claim 4, wherein the first sheet includes stainless steel, the second sheet includes graphite, and the third sheet includes stainless steel.

6. The backplate of claim 5, wherein a height of the backplate is no greater than about 2.67 mm.

7. The backplate of claim 1, wherein the thermal pad does not penetrate the second sheet.

8. The backplate of claim 7, wherein the first sheet includes a plurality of out-of-plane ribs formed by grooves.

9. The backplate of claim 8, wherein the third sheet includes a first raised wall along a first edge of the third sheet and a second raised wall along a second edge of the third sheet, the first raised wall being substantially perpendicular to the second raised wall.

10. The backplate of claim 9, wherein the first raised wall and the second raised wall extend from the third sheet toward the first sheet.

11. The backplate of claim 1, further comprising a plurality of separators attached to the third sheet, the separators extending through the second sheet and the first sheet.

12. The backplate of claim 10, wherein the first sheet includes a plurality of cutouts configured to accommodate electrical components, and the third sheet is devoid of the plurality of cutouts.

13. A printed circuit board comprising:
a front side comprising a plurality of electrical components;
a backside comprising a plurality of solder connections of the plurality of the electrical components; and
a backplate disposed along the backside, wherein the backplate comprises:
a first sheet;
a second sheet sandwiched between the first sheet and a third sheet, wherein the first sheet is disposed between the backside and the second sheet, the second sheet has a higher conductivity than that of the first sheet and the third sheet; and
a thermal pad penetrating the first sheet and contacting the second sheet.

14. The printed circuit board of claim 13, wherein the backplate further comprises an electrical insulation layer disposed between the first sheet and the second sheet, the thermal pad penetrating the electrical insulation layer.

15. The printed circuit board of claim 14, wherein the backplate further comprises an adhesion layer disposed between the second sheet and the third sheet.

16. The backplate of claim 15, wherein the first sheet includes stainless steel, the second sheet includes graphite, and the third sheet includes stainless steel.

17. The backplate of claim 13, wherein the first sheet includes a plurality of out-of-plane ribs formed by grooves.

18. The backplate of claim 17, wherein the third sheet includes a first raised wall along a first edge of the third sheet and a second raised wall along a second edge of the third sheet, the first raised wall being substantially perpendicular to the second raised wall, and the first raised wall and the second raised wall extend from the third sheet toward the first sheet.

19. The backplate of claim 18, further comprising a plurality of separators attached to the third sheet, the separators extending through the second sheet and the first sheet.

20. A method of protecting a printed circuit board (PCB), comprising:
dissipating heat generated by the PCB by a backplate, wherein the backplate comprises a second sheet sandwiched by a first sheet and a third sheet, wherein the second sheet has a higher conductivity than the first sheet and the third sheet, and the first sheet is disposed closer to a backside of the PCB than the second sheet and the third sheet;
transferring first thermal energy from the PCB to the first sheet, then to the second sheet, then to the third sheet; and
transferring second thermal energy from the PCB to a thermal pad, then to the second sheet, then to the third sheet, wherein the thermal pad penetrates the first sheet and contacts the second sheet.
